(19) United States
(12) Patent Application Publication
(10) Pub. No.: US 2025/0260332 A1
(43) Pub. Date: Aug. 14, 2025

(54) POWER CONVERSION APPARATUS AND HOME APPLIANCE INCLUDING THE SAME

(71) Applicants: LG ELECTRONICS INC., Seoul (KR); SEOUL NATIONAL UNIVERSITY R&DB FOUNDATION, Seoul (KR)

(72) Inventors: Jongseok Baek, Seoul (KR); Taeyoung Park, Seoul (KR); Junyeol Maeng, Seoul (KR); Shenghui Cui, Seoul (KR)

(73) Assignees: LG ELECTRONICS INC., Seoul (KR); SEOUL NATIONAL UNIVERSITY R&DB FOUNDATION, Seoul (KR)

(21) Appl. No.: 19/051,397

(22) Filed: Feb. 12, 2025

(30) Foreign Application Priority Data
Feb. 13, 2024 (KR) 10-2024-0020220

(51) Int. Cl. H02M 5/42; H02M 1/44; H03H 7/01; H03H 7/06

(52) U.S. Cl. CPC H02M 5/42; H02M 1/44; H03H 7/0161; H03H 7/06

(57) ABSTRACT

A power conversion apparatus included in a home appliance and including a converter configured to convert an AC power source into DC power and output the DC power to a DC terminal; a DC link capacitor connected to the DC terminal and configured to store DC power from the converter; an inverter configured to convert DC power from the DC link capacitor into AC power and output the converted AC power to a compressor; and a bandpass filter damper disposed between the input AC power source and the DC link capacitor and configured to allow a predetermined range of frequencies to pass through. Further, the bandpass filter damper is electrically connected to a ground of the input AC power source, thereby reducing the amount of leakage current flowing to the system ground.

### CROSS-REFERENCE TO RELATED APPLICATIONS

This application claims priority to Korean Patent Application No. 10-2024-0020220, filed in the Republic of Korea on Feb. 13, 2024, the entire contents of which is hereby expressly incorporated by reference into the present application.

### BACKGROUND

### 1. Field

The present disclosure relates to a power conversion apparatus and a home appliance including the power conversion apparatus. More particularly, the present disclosure relates to a power conversion apparatus that can effectively reduce leakage current and a home appliance including the power conversion apparatus.

### 2. Description of the Related Art

A power conversion apparatus (or device) is used to convert input power to output power. Most home appliances are equipped with a power conversion apparatus that converts input power to output power. A home appliance, which is designed for user convenience, is typically powered by a connected commercial power source. For example, a home appliance operates by converting AC power supplied from a commercial power source into DC power. A power conversion apparatus is provided in a home appliance, such as a refrigerator, an air conditioner, etc., to convert input power into power to drive the home appliance.

Meanwhile, electromagnetic interference (EMI) noise is generated while a home appliance is operating, and the EMI noise is classified as differential mode noise that flows through a power line through which power current flows and common mode noise that returns to a power source via the ground. For example, common mode noise may be caused by the switching operation of an inverter or caused by the leakage current from a motor.

Meanwhile, due to enhanced safety regulations, a growing number of countries require the use of GFCI (Ground Fault Circuit Interrupter) and AFCI (Arc Fault Circuit Interrupt) circuit breakers in power supply systems. In more detail, the GFCI circuit breakers are designed to detect a ground fault (grounding) in the circuit and interrupt power. Also, the AFCI circuit breakers are designed to protect fires caused by an arc fault by interrupting the flow of current. Some circuit breakers serve as both an AFCI breaker and a GFCI circuit breaker. Thus, the GFCI circuit breaker shuts off the circuit when it detects an abnormal current flow.

In addition, a malfunction may occur due to the leakage current of a home appliance, which causes a circuit breaker to trip and interrupt the circuit. For example, when the parasitic capacitance between a motor and a compressor shell of a refrigerator or the leakage current caused by switching of an inverter and the like flows to the power ground side, it may cause an unnecessary trip.

A related art document (Korean Registered Patent No. 10-1979452), which is hereby incorporated by reference, describes an active noise filter for reducing common mode noise. In particular, the active noise filter describe in the related art document is designed to block high-frequency common mode noise, requiring current sensing and an active element (or component) control algorithm. However, the related art active noise filter is not suitable for reducing common mode leakage current in a low-frequency range.

### SUMMARY OF THE DISCLOSURE

Accordingly, one object of the present disclosure is to provide a filter circuit that can reduce a leakage current.

Another object of the present disclosure is to provide a filter circuit that can prevent the malfunction of GFCI/AFCI circuit breakers applied to a system power ground.

Yet another object of the present disclosure is to provide a leakage current filter circuit including only passive elements, thereby requiring no separate sensing circuit and control logic, and reducing manufacturing costs.

Still another object of the present disclosure is to provide a power conversion apparatus that can improve efficiency and reliability, and a home appliance including the same.

The objects of the present disclosure are not limited to the objects described above, and other objects not stated herein will be clearly understood by those skilled in the art from the following description.

A power conversion apparatus and a home appliance according to embodiments of the present disclosure can prevent the malfunction of a circuit breaker by reducing a leakage current using a bandpass filter damper connected to a system ground.

To achieve these and other advantages and in accordance with the purpose of the present invention, as embodied and broadly described herein, the present invention provides in one aspect a power conversion apparatus included in a home appliance including a converter configured to convert an AC power source into DC power and output the DC power to a DC terminal; a DC link capacitor connected to the DC terminal and configured to store DC power from the converter; an inverter configured to convert DC power from the DC link capacitor into AC power and output the converted AC power to a compressor; and a bandpass filter damper configured to allow a predetermined range of frequencies to pass through. The bandpass filter damper can be disposed between the input AC power source and the DC link capacitor and can be electrically connected to a ground of the input AC power source, thereby reducing the amount of leakage current flowing to the system ground.

Further, the bandpass filter damper can include an inductor, a capacitor and a resistor connected in series between a live line of the input AC power source and a ground line; and an inductor, a capacitor and a resistor connected in series between a neutral line of the input AC power source and the ground line.

In addition, the bandpass filter damper can include capacitors connected in series between a live line of the input AC power source and a neutral line of the input AC power source; and an inductor and a resistor connected in series between a ground line and a first node between the capacitors.

The bandpass filter damper can further include resistors connected in series between a live line of the input AC power source and a neutral line of the input AC power source; and an inductor and a capacitor connected in series between a ground line and a second node between the resistors.

Also, the bandpass filter damper allows a part of a leakage current flowing to the ground of the input AC power source to pass through another path.

The bandpass filter damper can also be configured such that a center frequency is set based on a frequency component having the largest current magnitude in a leakage current generated in the compressor.

In addition, the power conversion apparatus and the home appliance can further include a Y capacitor disposed between the bandpass filter damper and the converter.

For example, the Y capacitor can include a first Y capacitor and a second Y capacitor connected in series between a live line of the input AC power source and a neutral line of the input AC power source. A node between the first and second Y capacitors can also be connected to a ground line.

Further, the power conversion apparatus included in the home appliance can further include an electromagnetic interference (EMI) filter disposed between the input AC power source and the bandpass filter damper.

The power conversion apparatus included in the home appliance can also include a Y capacitor and an EMI filter.

In addition, the EMI filter can include a capacitor connected between a live line of the input AC power source and a neutral line of the input AC power source; and a coil connected to the capacitor.

According to at least one embodiment of the present disclosure, as a bandpass filter damper configured to allow a predetermined range of frequencies to pass through is disposed between an input AC power source and a DC link capacitor and is electrically connected to a ground of the input AC power source the amount of leakage current flowing to a system ground can be reduced.

Also, as the bandpass filter damper includes an inductor, a capacitor and a resistor, which are connected in series between a live line of the input AC power source and a ground line, and an inductor, a capacitor and a resistor, which are connected in series between a neutral line of the input AC power source and the ground line, the bandpass filter can be formed with only passive elements.

Further, as the bandpass filter damper includes capacitors connected in series between a live line of the input AC power source and a neutral line of the input AC power source, an inductor, and a resistor, the inductor and the resistor being connected in series between a ground line and a first node between the capacitors, the number of elements can be reduced.

In addition, as the bandpass filter damper includes resistors connected in series between a live line of the input AC power source and a neutral line of the input AC power source, an inductor, and a capacitor, the inductor and the capacitor being connected in series between a ground line and a second node between the resistors, the number of elements can be reduced.

Also, as a Y capacitor is further provided between the bandpass filter damper and a converter, it is possible to further reduce electromagnetic interference (EMI) noise.

Further, as an EMI filter is further provided between the input AC power source and the bandpass filter damper, EMI noise can be reduced.

Further scope of applicability of the present invention will become apparent from the detailed description given hereinafter. However, the detailed description and specific examples, while indicating preferred embodiments of the invention, are given by illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings, which are given by illustration only, and thus are not limitative of the present invention, and wherein:

FIG. 1 is a circuit diagram of a power conversion apparatus according to an embodiment of the present disclosure.

FIG. 2 is another circuit diagram of a power conversion apparatus according to an embodiment of the present disclosure.

FIGS. 3 to 5 illustrate circuit diagrams of a bandpass filter damper according to various embodiments of the present disclosure.

FIG. 6 is a diagram illustrating an equivalent circuit of a bandpass filter damper according to embodiments of the present disclosure.

FIGS. 7A to 7C are diagrams illustrating an equivalent circuit of a bandpass filter damper according to embodiments of the present disclosure.

FIGS. 8 and 9 are circuit diagrams of a power conversion apparatus according to embodiments of the present disclosure.

FIG. 10 is a graph illustrating a grid current depending on the presence or absence of a bandpass filter damper according to an embodiment of the present disclosure.

FIGS. 11 and 12 are graphs results of frequency analysis of leakage current with and without a bandpass filter damper according to an embodiment of the present disclosure.

FIGS. 13 to 16 are diagrams illustrating a design method for a bandpass filter damper according to embodiments of the present disclosure.

### DETAILED DESCRIPTION OF THE EMBODIMENTS

Hereinafter, embodiments of the present disclosure will be described in detail with reference to the accompanying drawings. However, the present disclosure is not limited to these embodiments and can be modified in various forms. In the drawings, for the sake of clear and brief description, illustration of parts irrelevant to the description is omitted, and the same reference numerals are used for the same or similar parts throughout the specification.

In addition, the suffixes “module” and “unit” used in the following description are used interchangeably. Further, in this specification, terms such as “first” and “second” may be used to describe various elements, but these elements are not limited by these terms. These terms are used to distinguish one element from another.

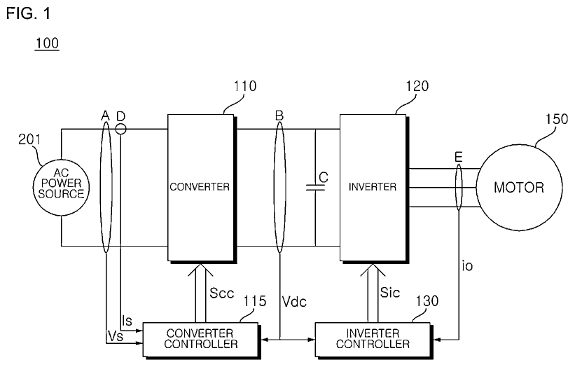

FIG. 1 is a circuit diagram of a power conversion apparatus 100 according to an embodiment of the present disclosure. Referring to FIG. 1, the power conversion apparatus 100 includes a converter 110 that converts input power into DC power and outputs the DC power to a DC terminal, a converter controller 115, a capacitor C connected to the DC terminal, an inverter 120 including a plurality of switching elements and converting DC power from the capacitor C into AC power, and an inverter controller 130 controlling the inverter 120. As shown, the power conversion apparatus 100 also includes an input voltage detector A, a DC voltage detector B, an input current detector D, and an output current detector E.

Further, the converter 110 converts a commercial AC power source 201 into DC power and outputs the DC power. Further, the converter 110 can include a rectifier and a reactor.

In more detail, the converter 110 converts the commercial AC power source 201 into DC power and then outputs the DC power to the DC terminal. FIG. 1 illustrates the commercial AC power source 201 as a single-phase AC power source, but a three-phase AC power source can also be used. In addition, the internal structure of the converter 110 varies depending on the type of the commercial AC power source 201.

Further, the converter 110 can include diodes and the like without a switching element, thereby performing a rectification operation without a switching operation. In this instance, the converter 110 can be referred to as a rectifier. For example, four diodes in the form of a bridge can be used for a single-phase AC power source, and six diodes in the form of a bridge can be used for a three-phase AC power source.

Further, the converter 110 can be, for example, a half-bridge type converter in which two switching elements and four diodes are connected. For a three-phase AC power source, the converter 110 can include six switching elements and six diodes.

When the converter 110 includes a switching element, voltage boosting, power factor correction, and DC power conversion can be achieved by a switching operation of the switching element. As shown in FIG. 1, the smoothing capacitor C is connected to an output terminal of the converter 110 and can store power output from the converter 110. The power output from the converter 110 is DC power, and thus, the capacitor C can be referred to as a DC link capacitor.

In an embodiment of the present disclosure, the power conversion apparatus 100 can employ a DC link capacitor C with a low capacitance of several tens of μF or less. For example, the low-capacitance DC link capacitor C can include a film capacitor instead of an electrolytic capacitor. Such a power conversion apparatus including a DC link capacitor C with a low capacitance (e.g., several tens of μF or less) can be referred to as a capacitorless power conversion apparatus. In addition, the inverter 120 outputs the converted AC power to a load such as a motor 150, etc. In addition, some of the loads, such as a compressor, can include a motor 150.

As shown in FIG. 1, the input voltage detector A can detect an input voltage Vs from the input AC power source 201. For voltage detection, the input voltage detector A can include a resistor, an operational amplifier (OP AMP), etc. Further, detected input voltage Vs can be applied to the inverter controller 130 in the form of a pulse type discrete signal.

In addition, the input voltage detector A can also detect a zero-crossing point of the input voltage. Also, the input current detector D can detect an input current Is from the commercial AC power source 201. For current detection, the input current detector D can include a current transformer (CT), a shut resistor, etc. The detected input current Is can be input to the inverter controller 130 in the form of a pulse type discrete signal, for calculation of power consumption.

Further, as shown in FIG. 1, the capacitor C for storing or smoothing the power converted by the converter 110 is provided at the output terminal of the converter 110. Both terminals of the capacitor C can be referred to as DC terminals. Therefore, the capacitor C can also be referred to as a DC link capacitor. Also, based on the input voltage Vs, the input current Is, and a DC link voltage Vdc, the converter controller 115 can generate a converter switching control signal Scc and then output the converter switching control signal Scc to the converter 110.

In addition, the DC voltage detector B can detect a DC link voltage Vdc across the smoothing capacitor C. In more detail, the DC voltage detector B can include a resistor, an amplifier, etc. The detected DC link voltage Vdc can be input to the inverter controller 130 in the form of a pulse type discrete signal.

Further, the inverter 120 can drive the motor 150 and include a plurality of inverter switching elements. In particular, the inverter 120 can convert the DC power Vdc smoothed by on/off operations of the switching elements into three-phase AC power having a predetermined frequency and then output the three-phase AC power to the three-phase synchronous motor 150.

In addition, the inverter 120 includes three pairs of arm switching elements connected in parallel, each arm switching pair including an upper arm switching element and a lower arm switching element connected in series. Diodes are also connected in anti-parallel to the respective switching elements.

Also, the switching elements included in the inverter 120 are switched on/off based on an inverter switching control signal Sic from the inverter controller 130. Accordingly, three-phase AC power having a predetermined frequency is output to the three-phase synchronous motor 150. In addition, the inverter controller 130 can control a switching operation of the inverter 120. Also, the inverter controller 130 can receive an output current iₒ detected by the output current detector E.

To control the switching operation of the inverter 120, the inverter controller 130 outputs the inverter switching control signal Sic to the inverter 120. In particular, the inverter switching control signal Sic is a pulse width modulation (PWM) switching control signal and is generated based on the output current iₒ detected by the output current detector E.

In addition, the output current detector E detects the output current iₒ flowing between the inverter 120 and the three-phase motor 150. That is, the output current detector E detects a current flowing through the motor 150. The output current detector E can also detect all output currents ia, ib, and ic of respective phases. Alternatively, the output current detector E can detect output currents of two phases using three-phase balancing.

Further, the output current detector E can be disposed between the inverter 220 and the motor 250. For current detection, a current transformer (CT), a shunt resistor, and the like can be used as the output current detector E.

When the shunt resistor is used, three shunt resistors can be provided between the inverter 120 and the synchronous motor 150 or can be connected at one end thereof to the three lower arm switching elements of the inverter 120, respectively. Alternatively, two shunt resistors can be employed through three-phase balance. When one shunt resistor is used, the shunt resistor can be provided between the aforementioned capacitor C and the inverter 120.

Also, the detected output current iₒ can be applied to the inverter controller 130 in the form of a pulse type discrete signal, and the inverter switching control signal Sic is generated based on the detected output current iₒ. In addition, the motor 150 can be a three-phase motor and includes a stator and a rotor. In particular, the rotor rotates as each phase AC power of a predetermined frequency is applied to a coil of each phase a, b, c of the stator.

Further, the motor 150 can include, for example, a surface-mounted permanent magnet synchronous motor (SMPMSM), an interior permanent magnet synchronous motor (IPMSM), a synchronous reluctance motor (Synrm), and the like. The SMPMSM and the IPMSM are each a permanent magnet synchronous motor (PMSM) employing a permanent magnet, whereas the Synrm has no permanent magnet.

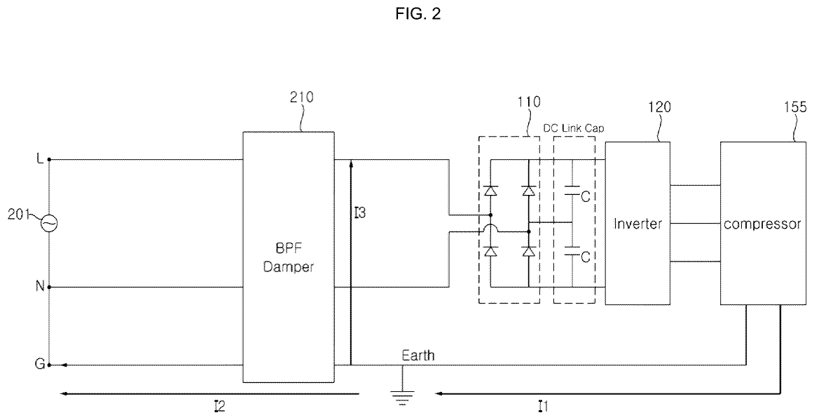

Next, FIG. 2 is a circuit diagram of a power conversion apparatus according to an embodiment of the present disclosure. Referring to FIG. 2, the power conversion apparatus 100 includes a converter 110 that converts an input AC power source 201 into DC power and outputs the DC power to a DC terminal, a DC link capacitor C connected to the DC terminal, and an inverter 120 that converts DC power from the DC link capacitor C into AC power.

In addition, the inverter 120 can supply converted power to a load such as a motor 150 to drive the motor 150. Also, the power conversion apparatus 100 can be provided in a home appliance, such as a refrigerator, an air conditioner, etc., to supply power to a compressor 155 for compressing a refrigerant. The inverter 120 supplies power to the compressor 155, and the compressor 155 can include a motor 150.

The power conversion apparatus 100 can further include a bandpass filter damper 210 that allows a predetermined range of frequencies to pass through. As shown in FIG. 2, the bandpass filter damper 210 is disposed between the input AC power source 201 and the DC link capacitor C.

Also, FIG. 2 illustrates that the DC link capacitor C is configured as a voltage doubler, including two capacitors connected in series. As a 110V AC power source is used in some countries, a voltage doubler method can be adopted to utilize higher voltages for loads such as motor driving, etc. In this instance, because the AC power source charges each of two capacitors, the total DC link voltage is twice that of a typical AC charge.

In addition, the present disclosure is not limited to the DC link capacitor C being configured as a voltage doubler. For example, as shown in FIG. 1, the DC link capacitor C can be configured as a single capacitor.

Further, the input AC power source 201 can be a grid commercial AC power source 201. As shown in FIG. 2, the input AC power source 201 can include a power line (L, N) to supply power, and a ground line G connected to a ground. The power line (L, N) can include a live line L and a neutral line N. Also, the input AC power source 201 can be configured as a three-phase four-wire (R, S, T, N) system. In this instance, the live line L can be replaced with a three-phase (R, S, T) line.

The ground of the input AC power source 201 can be earth, and a circuit breaker can be connected to the ground of the input AC power source 201. In addition, the circuit breaker can be a GFCI circuit breaker and/or an AFCI circuit breaker. As shown in FIG. 2, the bandpass filter damper 210 is also electrically connected to the ground of the input AC power source 201. As shown, a leakage current I1 can be generated in the compressor 155 due to a parasitic capacitance between the motor and a shell. When the leakage current I1 flows into the ground of the input AC power source 201, a malfunction can occur, causing the circuit breaker to trip unnecessarily.

To prevent such a malfunction of the circuit breaker, the bandpass filter damper 210 can allow a part I3 of the leakage current I1 generated in the compressor 155 to pass through another path. In particular, the part I3 of the leakage current I1 generated in the compressor 155 is induced to flow to the bandpass filter damper 210, and a remaining part I2 of the leakage current I1 generated in the compressor 155 flows to the ground of the input AC power source 201. Thus, the current flowing to the ground of the AC power source 201 can be reduced by the amount of current I2 guided to the bandpass filter damper 210 from the total leakage current I1.

Further, the bandpass filter damper 210 can be connected to the DC link capacitor C. For a model that further includes a Y capacitor, the bandpass filter damper 210 can be connected to the Y capacitor and the DC link capacitor C. Also, the capacitor affects the impedance, and the current I2 guided to the bandpass filter damper 210 can flow in a direction connected to the DC link capacitor C (the right (rightward) direction in FIG. 2). The leakage current is in the tens of kHz range, and the impedance is reduced by capacitance components on the right, allowing the leakage current to flow in the right direction.

In addition, the bandpass filter damper 210 is a filter that allows signals within a specific frequency range to pass through. A center frequency f0 is the geometric center of the frequency band transmitted by the bandpass filter damper 210. Also, the center frequency f0 and the bandwidth of the bandpass filter damper 210 can be separately set depending on the system and product.

Further, the bandpass filter damper 210 includes a resistor R, and can serve as a damper that dissipates energy caused by the leakage current. Meanwhile, the power line L, N can be connected to a chassis ground of a home appliance case. In some embodiments, the bandpass filter damper 210 can direct some of the leakage current to the chassis ground.

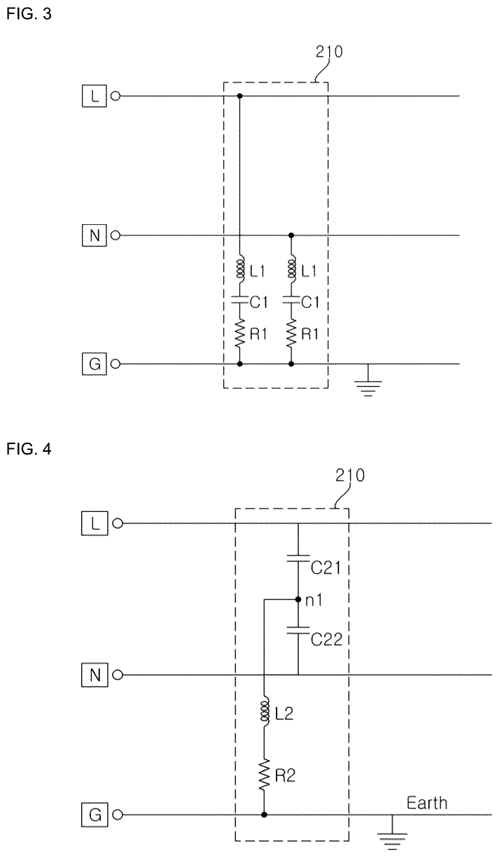

In addition, the bandpass filter damper 210 can be implemented by various structures. In more detail, FIGS. 3 to 5 are circuit diagrams according to various embodiments of the present disclosure. Referring to FIG. 3, the bandpass filter damper 210 can include an inductor L1, a capacitor C1 and a resistor R1, which are connected in series between a live line L of the input AC power source 201 and a ground line G, and an inductor L1, a capacitor C1 and a resistor R1, which are connected in series between a neutral line N of the input AC power source 201 and the ground line G.

As shown in FIG. 3, the bandpass filter damper 210 includes two sets of inductors L1, capacitors C1, and resistors R1 connected in series. Therefore, the bandpass filter 210 illustrated in FIG. 3 can be referred to as a ‘2-series’ type bandpass filter damper 210. The arrangement order of the inductor L1, the capacitor C1, and the resistor R1 included in one series line is not particularly limited.

Referring to FIG. 4, the bandpass filter damper 210 can include capacitors C21 and C22, which are connected in series between a live line L and a neutral line N of the input AC power source 201, an inductor L2, and a resistor R2, the inductor L2 and the resistor R2 being connected in series between a ground line G and a first node n1 between the capacitors C21 and C22. Accordingly, the number of elements can be reduced compared to the 2-series type. For the bandpass filter damper 210 illustrated in FIG. 4, a neutral point n1 is created by the two capacitors C21 and C22, and thus, can be referred to as ‘2C’ type.

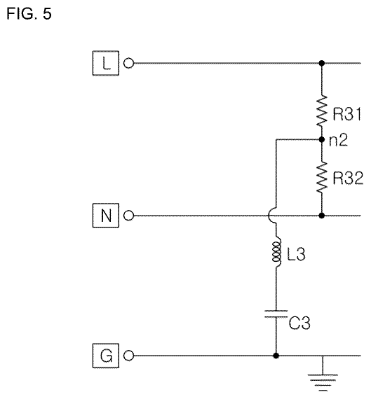

Referring to FIG. 5, the bandpass filter damper 210 includes resistors R31 and R32, which are connected in series between a live line L and a neutral line N of the input AC power source 201, an inductor L3, and a capacitor C3, the inductor L3 and the capacitor C3 being connected in series between a ground line G and a second node n2 between the resistors R31 and R32. Accordingly, the number of elements can be reduced compared to the 2-series type.

For the bandpass filter damper 210 illustrated in FIG. 5, a neutral point n2 is created by the two resistors R31 and R32, and thus, it can be referred to as ‘2R’ type. Also, a change in the arrangement order of passive elements connected in series can also be available for the ‘2C’ type and the ‘2R’ type.

In addition, the bandpass filter damper 210 can allow at least some of the frequency components of the leakage current generated in the compressor 155. Also, the center frequency and bandwidth of the bandpass filter damper 210 can be set or determined based on a frequency band of the main leakage current Il generated in the compressor 155 and flowing to the ground of the input AC power source 201. Further, the main leakage current I1 is measured, and the frequency band of the main leakage current I1 can be identified or obtained using a Fast Fourier Transform (FFT).

In addition, the bandpass filter damper 210 can allow some of the leakage current flowing to the ground of the input AC power source 201 to pass through another path. At least a part of the main leakage current I1 can be induced or guided to the bandpass filter damper 210 by the impedance sum of the bandpass filter damper 210 and connected circuit components. In this instance, a leakage current corresponding to a frequency band allowed to pass through the bandpass filter damper 210 can flow to the bandpass filter damper 210.

Further, the bandpass filter damper 210 absorbs and attenuates common mode (CM) leakage current generated in the motor of the compressor 155 and the inverter 120 before the leakage current flows to the power ground of the input AC power source 210 and causes the circuit breaker to malfunction. The bandpass filter damper 210 also prevents the leakage current from being conducted to the power ground by reducing the impedance in a specific frequency band on the current path.

As the bandpass filter damper 210 includes passive elements without a switching element, switching noise reduction is not required, thereby easily reducing common mode noise. Although FIG. 3 illustrates six passive elements connected in series to the live line L and the neutral line N of the input AC power source 201 are employed in the bandpass filter damper 210, another structure that can have the same effect by using fewer passive elements, e.g., four passive elements.

According to embodiments of the present disclosure, the malfunction of GFCI/AFCI circuit breakers can be prevented by reducing the amount of leakage flowing to the power ground. In addition, the stability and safety can be improved by reducing the leakage current itself.

Further, the current flowing to the bandpass filter band damper 210 is not large, ranging from a few milliamperes (mA) to several tens of milliamperes (mA), which allows small-capacity passive elements to be employed in the bandpass filter damper 210. Thus, the leakage current can be significantly reduced with a minimal increase in cost and size. Also, the circuits of the bandpass filter damper 210 illustrated in FIGS. 3 to 5 can each be replaced with an equivalent circuit.

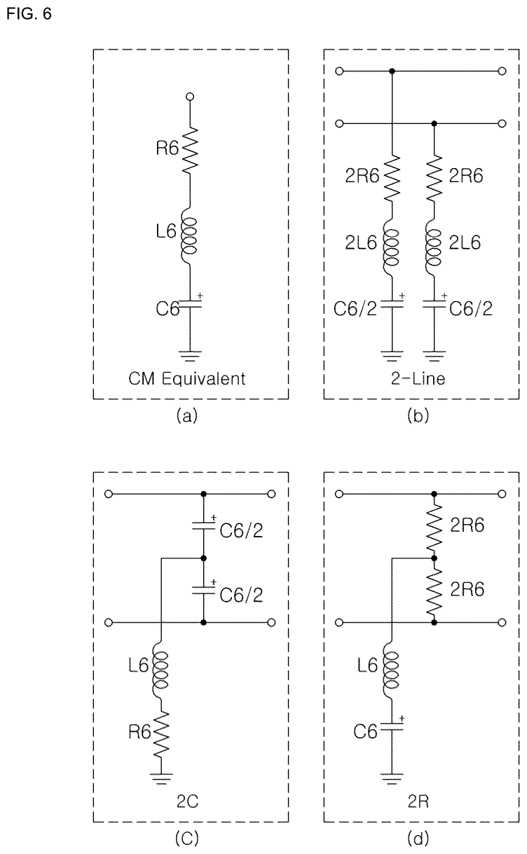

Next, FIG. 6 is a diagram illustrating an equivalent circuit of a bandpass filter damper according to different embodiments of the present disclosure. In particular, FIG. 6(a) illustrates a reference design value when the center frequency and bandwidth of a bandpass filter, obtained through leakage current frequency analysis, are designed to have typical resistance (R), inductance (L), and capacitance (C). The equivalent circuit of the design of FIG. 6(a) applied to the bandpass filter damper is shown in FIGS. 6(b), 6(c) and 6(d).

Referring to FIG. 6(b), compared to the RLC illustrated in FIG. 6(a), as for the 2-series type, the circuit is divided into two parallel paths from the leakage current's perspective, and preferably includes double the resistance and inductance, and with half (½) the capacitance.

Referring to FIG. 6(c), as for the 2C type, the L and the R are the same as the RLC in FIG. 6(a), but the capacitor appears as two parallel capacitors with respect to a virtual neutral point. Therefore, the equivalent circuit preferably includes half (½) the capacitance.

Referring to FIG. 6(d), as for the 2R type, the L and the C are the same as the RLC in FIG. 6(a), but the resistor appears as two parallel resistors with respect to a virtual neutral point. Therefore, the equivalent circuit preferably includes double the resistance.

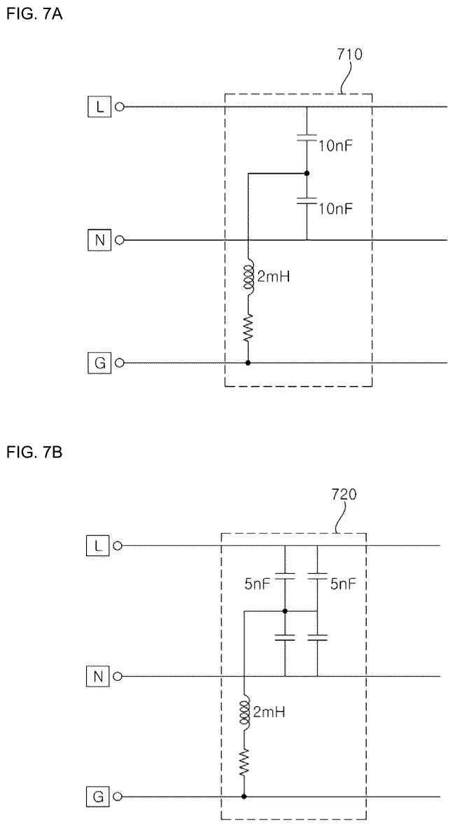

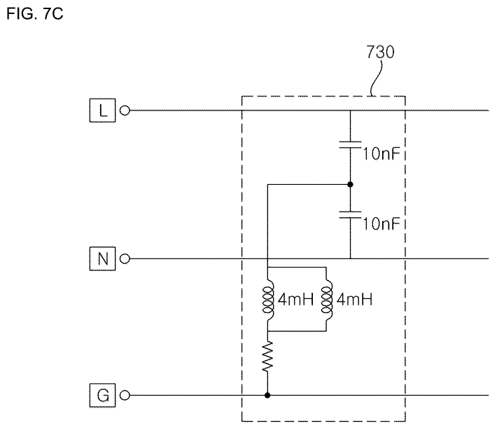

Next, FIGS. 7A to 7C are diagrams illustrating an equivalent circuit of a bandpass filter damper according to different embodiments of the present disclosure. A first circuit 710 illustrated in FIG. 7A is equivalent to a second circuit 720 illustrated in FIG. 7B and a third circuit 730 illustrated in FIG. 7C. Therefore, they can be replaced with the bandpass filter damper circuit illustrated as an example of the equivalent electric circuit, regardless of the number of elements (or components).

In addition, the 2-series type bandpass filter damper circuit can be replaced with the equivalent circuit regardless of series or parallel configuration. Further, a conventional EMI noise filter is designed to filter EMI noise in the range of several MHz, so its target filtering frequency is different from the bandpass filter damper designed to filter CM leakage current in the range of several kHz.

Also, unlike the conventional EMI noise filter, the bandpass filter damper includes only passive elements, which is advantageous in that a switch control algorithm and sensing for performing the switch control algorithm can be omitted. Meanwhile, the power conversion apparatus 100 according to the present disclosure can further include a mechanism for reducing electromagnetic interference (EMI) noise. For example, the power conversion apparatus 100 can further include an EMI filter and/or a Y capacitor.

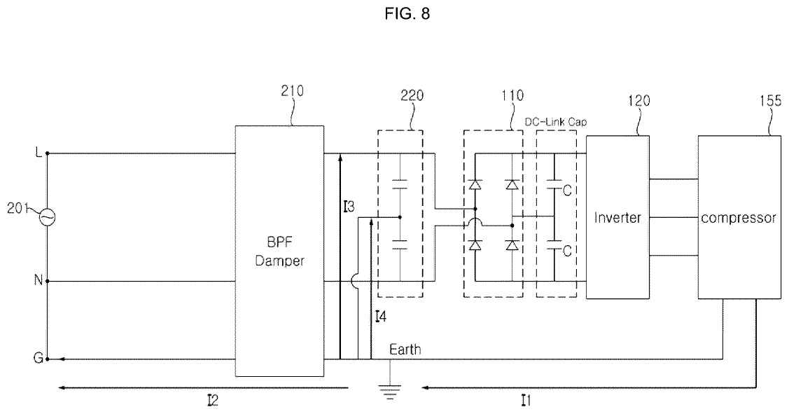

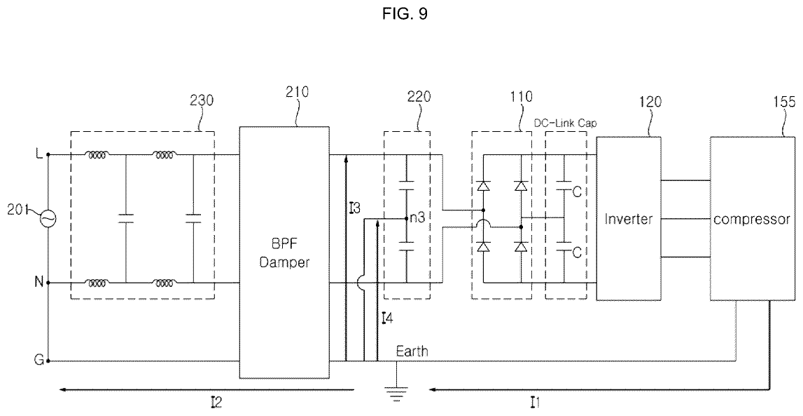

Next, FIGS. 8 and 9 are circuit diagrams according to embodiments of the present disclosure. Referring to FIG. 8, the power conversion apparatus 100 can further include a Y capacitor 220 disposed between the bandpass filter damper 210 and the converter 110.

Referring to FIG. 9, the power conversion apparatus 100 can further include an electromagnetic interference (EMI) filter 230 disposed between the input AC power source 210 and the bandpass filter damper 210. The Y capacitor 220 and the EMI filter 230 can use various known circuits. For example, the EMI filter 230 can include a capacitor connected between the live line L and the neutral line N of the input AC power source 210, and a coil connected to the capacitor. The coil of the EMI filter 230 can be a common mode (CM) choke. The CM choke, which is a coil used in the filter, can refer to a common mode coil.

Also, when the power conversion apparatus 100 further includes the EMI filter 230, if the bandpass filter damper 210 is provided at the previous stage of the EMI filter 230, its effect is reduced due to the influence of relatively high impedance of the EMI filter 230 when a leakage current is introduced into the bandpass filter 210. Therefore, the bandpass filter 210 is preferably provided at the post stage of the EMI filter 230.

Referring to FIGS. 8 and 9, the Y capacitor 220 can include a first Y capacitor and a second Y capacitor connected in series between the live line L and the neutral line N of the input AC power source 210. A node n3 between the first and second Y capacitors can be connected to the ground line G. That is, earth can be formed at the node n3 between the first and second Y capacitors.

As the power conversion apparatus 100 including the bandpass filter damper 210 further includes the Y capacitor 220 and/or the EMI filter 230, in addition to the third current I3 absorbed by the bandpass filter damper 210, a fourth current I4 can be removed or subtracted from the main leakage current I1, thereby further reducing the second current I2 flowing to the ground.

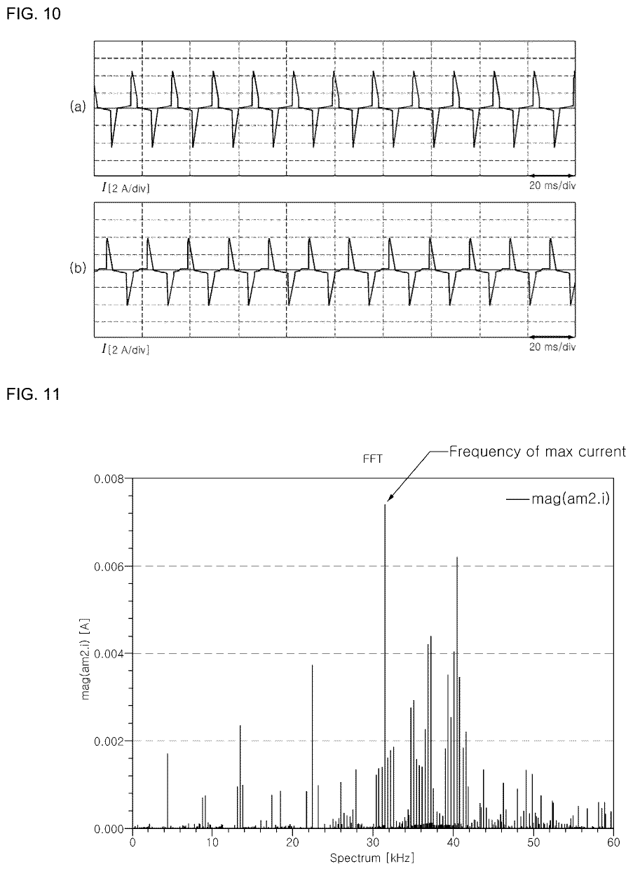

Next, FIG. 10 is a graph illustrating a grid current depending on the presence or absence of a bandpass filter damper according to an embodiment of the present disclosure. In particular, FIG. 10(a) illustrates a grid current flowing through the power conversion apparatus 100 when a bandpass filter damper is provided, and FIG. 10(b) illustrates a grid current flowing through the power conversion apparatus 100 when a bandpass filter damper is not provided. As shown in FIG. 10, there is no difference in the grid current whether the bandpass filter damper 210 is present or not, and therefore there is no impact on the grid.

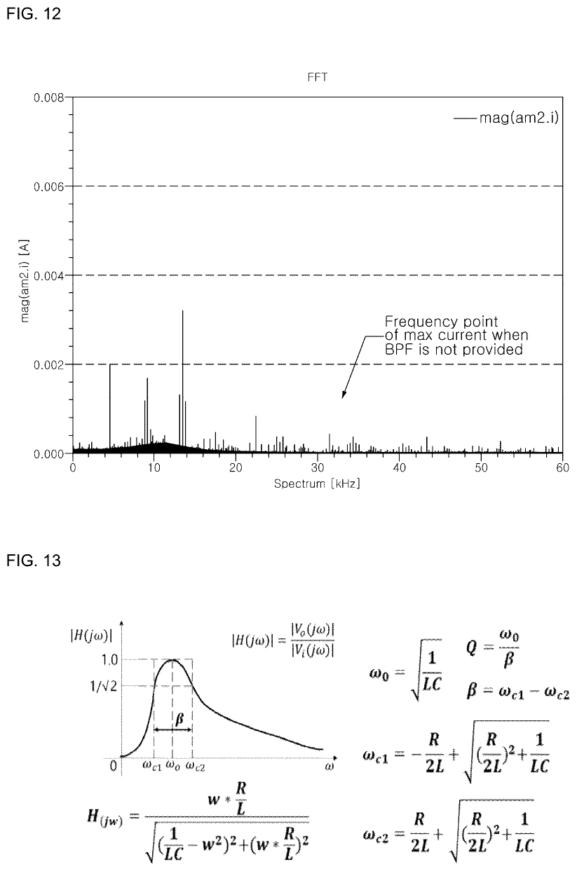

Next, FIGS. 11 and 12 are graphs illustrating results of frequency analysis of leakage current with and without a bandpass filter damper according to an embodiment of the present disclosure. In particular, FIG. 11 is a graph illustrating the result of frequency analysis of the second current I2 flowing to the ground when the bandpass filter damper is not provided, and FIG. 12 is a graph illustrating the result of frequency analysis of the second current I2 flowing to the ground when the bandpass filter damper is provided.

According to an embodiment of the present disclosure, as shown FIG. 11, the bandpass filter damper 210 can be designed by analyzing the frequency of the second current I2 flowing to the ground when the bandpass filter damper is not present, and determining a center frequency f0 based on a frequency band with the largest current magnitude. In addition, the bandpass filter damper 210 is designed to reduce the impedance of the largest current frequency source through frequency band analysis of leakage current conducting through parasitic capacitance of the compressor 155, such that the third current I3 is absorbed by the bandpass filter damper 210 to thereby reduce the amount of second current I2.

Further, the center frequency f0 of the bandpass filter damper 210 can be designed based on the frequency band having the largest current magnitude. For example, when the maximum frequency source is the 7^{th} harmonic, the center frequency f0 can be designed as the 7^{th} harmonic. In addition, when the minimum frequency source is the 7^{th} harmonic, the bandpass filter damper 210 can be designed to reflect the 4^{th} harmonic to 10^{th} harmonic frequency range.

By utilizing the property that the leakage current of various frequency components flows toward the lower impedance inside the circuit, a leakage current in a target frequency band flows to the predetermined bandpass filter damper 210 to thereby reduce the amount of second current I2.

Referring to FIG. 12, as the bandpass filter damper 210 is employed, it can be seen that the frequency source having the largest current magnitude when the bandpass filter damper 210 is not present is greatly reduced.

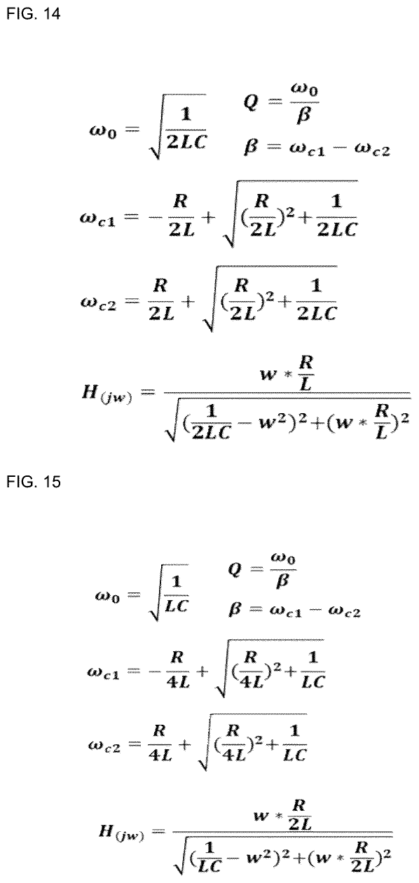

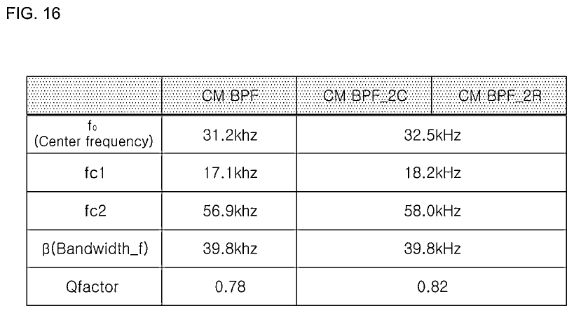

Next, FIGS. 13 to 16 are diagrams illustrating a design method for a bandpass filter damper according to embodiments of the present disclosure. In particular, FIG. 13 illustrates a design method for a transfer function, a center frequency, and a bandwidth of a 2-series type bandpass filter damper. Also, FIG. 14 illustrates a design method for a transfer function, a center frequency, and a bandwidth of a 2C type bandpass filter damper, and FIG. 15 illustrates a design method for a transfer function, a center frequency, and a bandwidth of a 2R type bandpass filter damper. Further, FIG. 16 illustrates an example of specific design values of three types of bandpass filter damper.

In addition, a center frequency f₀ is the geometric center of a frequency band transmitted by the bandpass filter damper 210. A bandwidth β of the bandpass filter damper 210 is the interval (difference) between a lower cutoff frequency fc1 and an upper cutoff frequency fc2. The quality factor represents a ratio of the center frequency f0 to the bandwidth β.

Referring to FIGS. 13 to 16, the center frequency f₀ is designed based on the highest frequency band in the leakage current obtained through the frequency analysis result. Compared to the 2-series type, the passive elements R, L, and C of the 2C type design appear as R, L, and 2C from the filter's perspective, requiring a change in the design value. The modified transfer function is illustrated in FIG. 14.

Compared to the 2-series type, the passive elements R, L, and C of the 2R type design appear as R/2, L, and C from the filter's perspective, requiring a change in the design value. The modified transfer function is illustrated in FIG. 15.

For the 2-series type, when specific values of the respective passive elements are R: 1 kΩ, L: 4 mH, and C: 6.5 nF, the electric characteristic result can be represented as ‘CM BPF’ shown in the table of FIG. 16. For the 2C type, when specific values of the respective passive elements are R: 0.3 kΩ, L: 1.2 mH, and C: 10 nF, the electric characteristic result can be represented as ‘CM BPF_2C’ shown in the table of FIG. 16. For the 2R type, when specific values of the respective passive elements are R: 1.2 kΩ, L: 2.4 mH, and C: 10 nF, the electric characteristic result can be represented as ‘CM BPF_2R’ shown in the table of FIG. 16.

In addition, as described above, the power conversion apparatus 100 described above with reference to FIGS. 1 to 16 can be provided in various home appliances. For example, the power conversion apparatus 100 is applicable to various apparatuses such as a refrigerator, a laundry treating apparatus (e.g., a washing machine, a dryer, etc.), an air conditioner, and the like.

A power conversion apparatus and a home appliance including the power conversion apparatus are not limited to the configurations and the methods of the embodiments described above, but all or some of the embodiments can be selectively combined so that various modifications can be made.

Although preferred embodiments of the present disclosure have been shown and described herein, the present disclosure is not limited to the specific embodiments described above. It will be understood that various modifications and changes can be made by those skilled in the art without departing from the idea and scope of the present disclosure as defined by the appended claims.

What is claimed is:

1. A power conversion apparatus comprising:
a converter configured to convert an AC power source into DC power and output the DC power to a DC terminal;
a DC link capacitor connected to the DC terminal and configured to store DC power from the converter;
an inverter configured to convert DC power from the DC link capacitor into AC power and output the converted AC power to a compressor; and
a bandpass filter damper disposed between the input AC power source and the DC link capacitor and configured to allow a predetermined range of frequencies to pass through,
wherein the bandpass filter damper is electrically connected to a ground of the input AC power source.

2. The power conversion apparatus of claim 1, wherein the bandpass filter damper comprises:
an inductor, a capacitor and a resistor connected in series between a live line of the input AC power source and a ground line; and
an inductor, a capacitor and a resistor connected in series between a neutral line of the input AC power source and the ground line.

3. The power conversion apparatus of claim 1, wherein the bandpass filter damper comprises:
capacitors connected in series between a live line of the input AC power source and a neutral line of the input AC power source; and
an inductor and a resistor connected in series between a ground line and a first node between the capacitors.

4. The power conversion apparatus of claim 1, wherein the bandpass filter damper comprises:
resistors connected in series between a live line of the input AC power source and a neutral line of the input AC power source; and
an inductor and a capacitor connected in series between a ground line and a second node between the resistors.

5. The power conversion apparatus of claim 1, wherein the bandpass filter damper is configured to allow a part of a leakage current flowing to the ground of the input AC power source to pass through another path.

6. The power conversion apparatus of claim 1, wherein a center frequency of the bandpass filter damper is set based on a frequency component having a largest current magnitude in a leakage current generated in the compressor.

7. The power conversion apparatus of claim 1, further comprising a Y capacitor disposed between the bandpass filter damper and the converter.

8. The power conversion apparatus of claim 7, wherein the Y capacitor comprises a first Y capacitor and a second Y capacitor connected in series between a live line of the input AC power source and a neutral line of the input AC power source, and
wherein a node between the first and second Y capacitors are connected to a ground line.

9. The power conversion apparatus of claim 7, further comprising an electromagnetic interference (EMI) filter disposed between the input AC power source and the bandpass filter damper.

10. The power conversion apparatus of claim 9, wherein the EMI filter comprises:
a capacitor connected between a live line of the input AC power source and a neutral line of the input AC power source; and
a coil connected to the capacitor.

11. The power conversion apparatus of claim 1, further comprising an electromagnetic interference (EMI) filter disposed between the input AC power source and the bandpass filter damper.

12. A home appliance comprising:
a power conversion apparatus,
wherein the power conversion apparatus comprises:
a converter configured to convert an input AC power source into DC power and output the DC power to a DC terminal;
a DC link capacitor connected to the DC terminal and configured to store DC power from the converter;
an inverter configured to convert DC power from the DC link capacitor into AC power and output the converted AC power to a compressor; and
a bandpass filter damper disposed between the input AC power source and the DC link capacitor and configured to allow a predetermined range of frequencies to pass through, and
wherein the bandpass filter damper is electrically connected to a ground of the input AC power source.

13. The home appliance of claim 12, wherein the bandpass filter damper comprises:
an inductor, a capacitor and a resistor connected in series between a live line of the input AC power source and a ground line; and
an inductor, a capacitor and a resistor connected in series between a neutral line of the input AC power source and the ground line.

14. The home appliance of claim 12, wherein the bandpass filter damper comprises:
capacitors connected in series between a live line of the input AC power source and a neutral line of the input AC power source; and
an inductor and a resistor connected in series between a ground line and a first node between the capacitors.

15. The home appliance of claim 12, wherein the bandpass filter damper comprises:
resistors connected in series between a live line of the input AC power source and a neutral line of the input AC power source; and
an inductor and a capacitor connected in series between a ground line and a second node between the resistors.

16. The home appliance of claim 12, wherein the bandpass filter damper is configured to allow a part of a leakage current flowing to the ground of the input AC power source to pass through another path.

17. The home appliance of claim 12, wherein a center frequency of the bandpass filter damper is set based on a frequency component having the largest current magnitude in a leakage current generated in the compressor.

18. The home appliance of claim 12, further comprising a Y capacitor disposed between the bandpass filter damper and the converter.

19. The home appliance of claim 18, wherein the Y capacitor comprises a first Y capacitor and a second Y capacitor connected in series between a live line of the input AC power source and a neutral line of the input AC power source, and
wherein a node between the first and second Y capacitors are connected to a ground line.

20. The home appliance of claim 19, wherein the power conversion apparatus further comprises an electromagnetic interference (EMI) filter disposed between the input AC power source and the bandpass filter damper, and
wherein the EMI filter comprises:
a capacitor connected between the live line of the input AC power source and the neutral line of the input AC power source; and
a coil connected to the capacitor.
